(19) United States
(12) Patent Application Publication
(10) Pub. No.: US 2008/0280099 A1
(43) Pub. Date: Nov. 13, 2008

(54) Silicon Substrates with Thermal Oxide Windows for Transmission Electron Microscopy

(76) Inventors: James E. Hutchison, Eugene, OR (US); Gregory J. Kearns, Eugene, OR (US)

Correspondence Address: KLARQUIST SPARKMAN, LLP, 121 SW SALMON STREET, SUITE 1600, PORTLAND, OR, 97204, US

(21) Appl. No.: 11/921,056

(22) PCT Filed: May 23, 2006
(86) PCT No.: PCT/US2006/019971

§ 371 Date: Nov. 23, 2007

Related U.S. Application Data
(60) Provisional application No. 60/683,916, filed on May 23, 2005.

(51) Int. Cl. B32B 3/10; H01B 13/00; G03F 7/20

(52) U.S. Cl. 428/138; 216/17; 430/311

(57) ABSTRACT

Silicon grids with electron-transparent SiO₂ windows for use as substrates for high-resolution transmission electron microscopy of chemically-modified SiO₂ surfaces are fabricated by forming an oxide layer on a silicon substrate. An aperture is defined in the silicon substrate by etching the substrate to the oxide layer. A single substrate can include a plurality of apertures that are in respective frame regions that are defined by one or more channels in the substrate. Tabs are provided to secure the frame regions to the substrate, and the tabs are readily broken to obtain a particular frame region. Conductive or other features can be defined on the oxide layers prior to separation of the frame regions from the substrate.

### CROSS-REFERENCE TO RELATED APPLICATIONS

This application claims the benefit of U.S. Provisional Application 60/683,916, filed May 23, 2005, which is incorporated herein by reference.

### ACKNOWLEDGMENT OF GOVERNMENT SUPPORT

The U.S. Government has a paid up license in this invention and the right in limited circumstances to require the patent owner to license on reasonable terms as provided by the terms of contract DGE-0114419 awarded by the National Science Foundation.

### TECHNICAL FIELD

The disclosure pertains to substrates for transmission electron microscopy.

### BACKGROUND

An important challenge in nanoscience is the characterization and analysis of structures that are assembled on technologically relevant substrates. A number of scanning probe and electron beam-based microscopies have been employed, each possessing unique advantages, complexities and substrate requirements. Imaging performance is typically enhanced through the use of specialized substrates. Unfortunately, such substrates are often chemically dissimilar to the substrates used in devices or during assembly reactions. For example, a carbon-coated TEM grid has different surface chemistry than a semiconductor wafer.

The most commonly used methods for analyzing nanostructures on chemically functionalized surfaces are atomic force microscopy (AFM) and scanning electron microscopy (SEM) because these techniques are compatible with a wide range of substrates including SiO₂. In a direct comparison of AFM, SEM, scanning near-field optical microscopy (SNOM) and transmission electron microscopy (TEM), Grabar et al. demonstrated that TEM is a preferred method for quantifying the size, shape, and spacing of nanoparticles in nanoparticle arrays due to high lateral resolution and straightforward data analysis. Grabar et al., Anal. Chem. 1997, 69, 471-477. The primary limitation of using TEM to analyze nanostructures is that the relevant substrate material may not be available as a support film on commercially available grids. In order to obtain images of samples on relevant substrates, time-intensive, destructive sample preparation techniques such as mechanical polishing or ion milling must be employed in order to obtain electron transparency.

Commercially available silicon monoxide (SiOₓ) TEM grids are often used as approximants for SiO₂ surfaces. These substrates generally consist of a metal grid coated with a polymer support that is coated with a substrate material such as SiO or carbon. Unfortunately, these substrates are rough, lack rigidity, and the SiOₓ surfaces have an ambiguous chemical structure that is a mixture of SiO and SiO₂. Therefore, such surfaces do not have the same chemical reactivity as native or thermally grown SiO₂ on silicon. Due to the reactivity of the polymer coated metal grid that supports such SiOₓ films, these grids cannot withstand even the mildest environments that are used for cleaning and processing SiO₂/Si. UV/ozone cleaning destroys the polymer support, as do RCA SC-1, piranha solution, and oxygen plasma, while RCA SC-2 or other acidic environments will dissolve most metal substrates. In addition, the chemical environments used to functionalize SiO₂, such as self-assembled monolayer chemistry, often involve acidic environments and organic solvents. The ideal TEM grid for imaging SiO₂ surfaces must be electron transparent, smooth, rigid, and robust to chemical processing.

Recently, it has been shown that the surfaces of silicon nitride TEM grids can be oxidized to SiO₂ by O₂ plasma treatment, but the chemical nature and reactivity of such surfaces has not been determined. See Grant et al., Nanotechnology 2004, 15, 1175. Because thermal oxides react differently to surface treatments than native oxides due to the nature of the surface hydroxyl groups, surfaces with a stoichiometry of SiO₂ are not necessarily equivalent. Thus it cannot be assumed that the images obtained from an oxidized silicon nitride TEM grid represent the surface of a similarly treated glass slide or silicon chip.

TEM grids with electron-transparent Si₃N₄ windows are commercially available. While Grant et al. report that grids of this type can be oxidized in an oxygen plasma to produce an SiO₂ surface, analytical data and the chemical reactivity of these surfaces have not been reported. Grant et al., “Transmission electron microscopy ‘windows’ for nanofabricated structures,” Nanotechnology, 2004, 15, 1175-1181. Kennedy et al. report that the chemical composition of oxidized silicon nitride surfaces depends noticeably on the method of oxidation, ranging from an oxynitride composition at lower levels of oxidation toward a “silicon oxide rich” layer after more extensive oxidation. Kennedy et al, “Oxidation of silicon nitride films in an oxygen plasma,” J. Appl. Phys., 1999, 85, 3319-3326. Ito et al. have reported that the reactivity of the “native oxide” on silicon nitride depends on the method of sample preparation. Ito et al., “Modification of Silicon Nitride Tips with Trichlorosilane Self-Assembled Monolayers (SAMs) for Chemical Force Microscopy,” Langmuir, 1997, 13, 4323-4332. Given the marked dependence of the surface reactivity of silicon dioxide and oxidized silicon nitride on the method of preparation (e.g. native oxide and thermal oxide exhibit different reactivity due, in part, to the differences in surface hydroxyl concentration), it remains to be seen whether oxidized silicon nitride surfaces will serve as suitable approximants for a thermal silicon dioxide surface. From the data published for the oxidized silicon nitride grids and the other precedent in the chemical literature, it appears unlikely that these grids will exhibit the surface reactivity found for thermal silicon dioxide.

### SUMMARY

Novel TEM substrates comprise a silicon grid with electron transparent SiO₂ windows. These grids are smooth as measured by AFM in tapping mode. The RMS roughness of the substrate surface has been measured to be about 0.8 Å±0.08 Å over a 100 nm×100 nm area. Such substrates can be cleaned with, for example, UV/ozone, piranha solution, RCA SC-1 and SC-2 solutions, and oxygen plasma. In addition, surfaces of the SiO₂ windows have been chemically modified with self-assembled monolayers and chemically bound nanoparticle arrays. The SiO₂ surfaces are robust, cleanable, and amenable to a variety of selective chemical modifications. Such SiO₂ surfaces can be used as surfaces on which selected reactions occur, and permit direct images of reaction products using, for example, transmission electron microscopy. Representative examples of reactions that can be obtained and imaged include self-assembly of monolayers and formation of chemically bound nanoparticle arrays.

These TEM grids can be used to, for example, image nanoparticle structures such as a linear array of nanoparticles templated by strands of DNA. DNA can be used as a template to organize close packed arrays of gold nanoparticles and that the spacing between nanoparticles can be controlled by the choice of organic ligand shell on the nanoparticles. In order to make devices, a DNA template is selected, and the strands can be coated with close packed arrays of nanoparticles.

In an example, SiO₂ TEM grids were cleaned by UV/ozone for 15 minutes followed by rinsing with ethanol and water, then dried at 60° C. for 1 hr. The clean grids were then silanized overnight by vapor phase deposition of n-octyltrichlorosilane. DNA was aligned on the grids by molecular combing such as developed by Bensimon et al. The DNA arrays were coated with nanoparticles by soaking the grids in thiocholine stabilized 1.4 nm Au-nanoparticles for 20 min. The resulting nanoparticle arrays were rinsed thoroughly with nanopure water and characterized by TEM. The resulting arrays are substantially linear over the entire surface and single strands are substantially linear over the entire length of the DNA molecule. Branching of the DNA may be due to splitting of dsDNA or multiple DNA molecules interacting at the complimentary “sticky ends” of λ-DNA.

In some examples, substrates comprise a silicon layer in which an aperture is defined, wherein the aperture is terminated at a window surface by an electron-transmissive oxide layer. In additional examples, the oxide layer is less than about 100 nm thick or less than about 50 nm thick. The silicon layer can have a thickness of between about 50 μm and 1 mm, and in some examples, an exterior surface of the oxide layer is functionalized by, for examples, silanization. In further examples, an inorganic layer of thickness less than about 50 nm situated on an exterior surface of the oxide layer, or an array of nanoparticles is situated on the exterior surface of the oxide layer at at least one window. In other examples, a plurality of apertures are provided on the substrate.

According to representative examples, methods include forming a window layer on at least one surface of a substrate, and exposing the substrate to an etchant to form at least one aperture, wherein an etch rate of the substrate as exposed to the etchant is substantially larger than an etch rate of the window layer as exposed to the etchant. In some examples, a surface of the substrate opposite the window layer is patterned to define a location for the at least one aperture. In other examples, window layers are formed on opposing surfaces of the substrate, and one of the window layers is patterned to pattern the substrate. In additional representative examples, the substrate is silicon and window layers of SiO₂ are formed on opposite faces of the substrate. A selected window layer is photolithographically patterned, and the substrate layer is etched based on the photolithographic patterning of the selected window layer so as to define at least one aperture that extends to the other window layer. In some examples, the substrate is about 100 μm thick and the window layers are about 50 nm thick and are formed as thermal oxide of the substrate layer.

In further representative embodiments, substrates comprise a first window frame region defined in the substrate by a substrate channel. At least one window is defined in the first window region, and at least one tab attaches the first window frame region to the substrate. In some examples, the substrate is a silicon substrate, the window consists essentially of silicon oxide, and the substrate channel extends through the substrate. In additional examples, the window includes at least one electrical conductor situated on a surface of the at least one window. In further examples, the substrate includes a plurality of window frames, each window frame defining a plurality of windows and a plurality of tabs configured so that each window frame is connected by at least one tab to either a different window frame or the substrate. In some examples, a window includes a silicon oxide layer having a thickness of between about 10 nm and 500 nm.

Methods of making a specimen substrate include the steps of defining a window frame in a substrate by thinning the substrate in a channel region and defining an aperture in the window frame, the aperture terminating at a window layer. The window frame is separated from the substrate at the channel region. In representative examples, the window frame is secured to the substrate at at least one tab, and the window frame is separated from the substrate by breaking the tab. In further examples, the substrate is silicon, and the aperture is terminated at a silicon oxide layer.

These and other features and aspects of the disclosed technology will become more apparent from the following detailed description, which proceeds with reference to the accompanying drawings.

### BRIEF DESCRIPTION OF THE DRAWINGS

FIG. 1 is a block diagram illustrating a method of making a TEM grid.

FIG. 2 illustrates a substrate undergoing processing according to the method of FIG. 1.

FIG. 3a is a view of a substrate in which an array of SiO₂ windows have been formed.

FIG. 3b is an image of a single SiO₂ window with a dust particle that verifies that a window layer is present.

FIG. 3c is a back view of the substrate of FIG. 3a showing an array of windows and Si(111) etch planes within the windows.

FIG. 3d is a back view of a single window showing the Si(111) etch planes and residual SiO₂ flakes around the larger portion of the window.

FIGS. 4a-4b are TEM images of DNA templated nanoparticle arrays.

FIGS. 5a-5b are graphs illustrating distributions of interparticle spacing for DNA nanoparticle assemblies formed using normally prepared Au-thiocholine particles and ultrapure Au-thiocholine particles, respectively. (Thiocholine can be abbreviated as “TMAT” for convenience.)

FIGS. 6a-6d illustrate nanoparticle size distributions based on TEM images for normally prepared nanoparticles (FIG. 6a) and ultrapure nanoparticles (FIG. 6b). After assembly on DNA, normally prepared particles grow to 2.7±0.9 nm (n=321) (FIG. 6c), while ultrapure particles become more monodisperse via size selection, having a diameter of 1.4±0.5 nm (n=706) (FIG. 6d).

FIG. 7a illustrates the structure of normally prepared Au-thiocholine assemblies that are generally configured as linear arrays 1-2 nanoparticles wide.

FIG. 7b illustrates the structure of “ribbons” formed with ultrapure particles. The ribbons are typically about 4-5 nanoparticles wide.

FIG. 8a is a schematic diagram of a mask that includes pattern areas for a plurality of grids.

FIG. 8b is a schematic diagram of a representative grid that includes a plurality of SiO₂ windows.

FIG. 9a is a schematic diagram of a silicon substrate on which a plurality of TEM grids are defined.

FIG. 9b is a schematic diagram of one of the TEM grids of FIG. 9a.

### DETAILED DESCRIPTION

As used in this application and in the claims, the singular forms “a,” “an,” and “the” include the plural forms unless the context clearly dictates otherwise. Additionally, the term “includes” means “comprises.” The described systems, apparatus, and methods described herein should not be construed as limiting in any way. Instead, the present disclosure is directed toward all novel and non-obvious features and aspects of the various disclosed embodiments, alone and in various combinations and sub-combinations with one another. The disclosed systems, methods, and apparatus are not limited to any specific aspect or feature or combinations thereof, nor do the disclosed systems, methods, and apparatus require that any one or more specific advantages be present or problems be solved.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed systems, methods, and apparatus can be used in conjunction with other systems, methods, and apparatus. Additionally, the description sometimes uses terms like “produce” and “provide” to describe the disclosed methods. These terms are high-level abstractions of the actual operations that are performed. The actual operations that correspond to these terms will vary depending on the particular implementation and are readily discernible by one of ordinary skill in the art.

Silicon-based TEM grids are described that include electron transparent SiO₂ windows. Such TEM grids are useful for investigation of surface chemical interactions on SiO₂ and high-resolution TEM imaging of nanostructures assembled on the SiO₂ surface. Representative silicon TEM grids can have dimensions similar to those of conventional TEM grids that include 30 μm square windows on a 3 mm diameter substrate, but other substrate and window sizes can be selected. The number and shape of the transmissive SiO₂ windows can also be varied. Such silicon-based grids can be chemically treated in the same manner that thermal oxides on silicon are treated and imaged directly without any further sample preparation. The grids can withstand a variety of harsh treatments including exposure to UV radiation, ozone, piranha solution, RCA SC-1 and SC-2 solutions, other cleaning solutions, and oxygen plasma. Chemical reactions on the SiO₂ windows of the grids can also be followed by other analytical methods such as XPS or AFM.

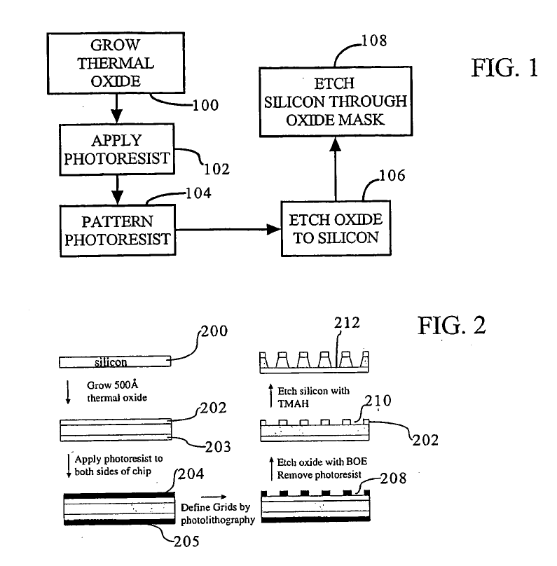

A representative method of fabricating illustrative examples of the disclosed grids is illustrated in FIGS. 1-2. In a step 100, a 500 Å thermal oxide was grown at 1100° C. under flowing O₂ on opposing surfaces of an RCA SC-1 cleaned silicon substrate. Other thicknesses can be selected, but thermal oxide thicknesses are between about 10 Å and 5000 Å, 100 Å and 2500 Å, or preferably between about 200 Å and 2000 Å, or more preferably between about 100 Å and 1000 Å. The silicon substrate was 100 μm thick and was polished on both sides. Thinner or thicker substrates can be used, but substrates having thicknesses of less than about 5 mm are typically convenient. Such substrates are available from, for example, Virginia Semiconductor, Fredericksburg, Va. as ULTRATHIN silicon. In a step 102, both surfaces of the substrate were coated with positive photoresist, and in a step 104, grid patterns were defined by photolithography on one side using a contact mask. In a step 106, exposed portions of the SiO₂ layer were etched in a 20:1 buffered oxide etch (BOE) for a time sufficient to etch through the SiO₂ layer to a surface of the silicon layer. The photoresist was removed, and the exposed silicon was etched in a step 108 with a 10% (wt %) tetramethylammonium hydroxide (TMAH) solution. The TMAH solution was arranged to be at about 90° C. when etching began, but once the etch was underway, the TMAH solution was cooled to room temperature and allowed to etch through the silicon overnight. The substrate was placed in the TMAH solution “patterned side up” to prevent trapping of gas bubbles in the etching area.

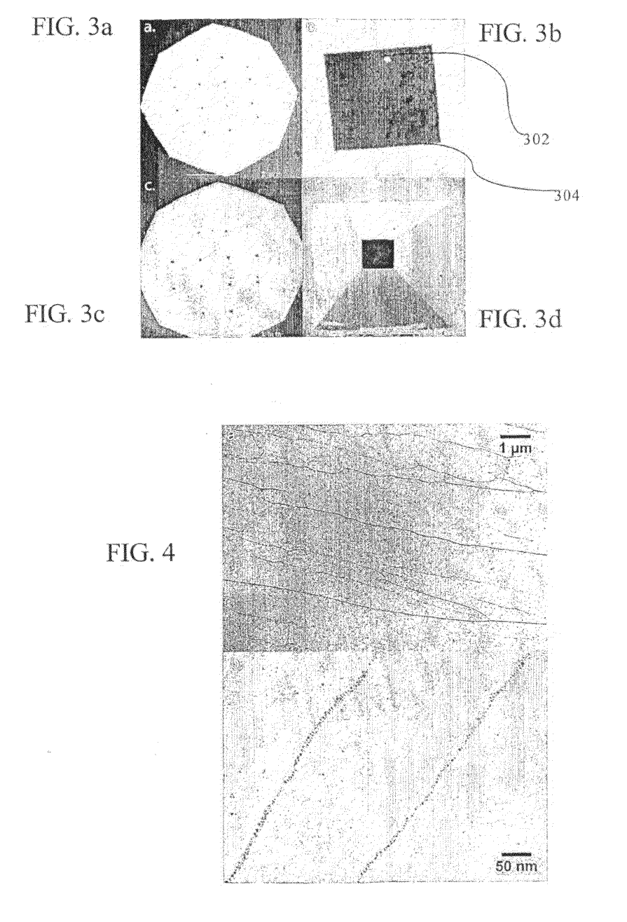

As shown in FIG. 8a, a mask 800 such as a photomask has areas that define a plurality of grids in representative pattern areas 802, 804, 806, 808. The mask 800 can be used to define patterned chip areas and can include pattern areas for additional grids or other structures that can be used as desired. A representative grid 810 is shown in FIG. 8b and includes a plurality of SiO₂ windows such as a representative window 812. If a ˜1.5 cm square chip is used to make the grids, 16 grids (3 mm in diameter each, 4 rows of 4 grids) can be fabricated on one chip. These grids are circular/octagonal as can be seen in FIG. 3a and FIG. 3c, and when the TMAH etches through the chip, the grids separate from the chip into 16 separate grids. As shown in FIG. 8b, the grid includes 12 windows, but different numbers of windows per grid and grids per chip can be used, and the numbers need not be equal. In a representative example, the grids are defined by a mask having pattern areas for 20 grids (4 rows of 5 grids), but only 16 of these grids fit onto a 1.5 cm square chip. With grids defined as shown in FIG. 8a, etching could be conveniently considered as complete when the grids (16 per 1.5 cm square chip) separated from each other. The resulting TEM grids include 16 TEM apertures having a 500 Å thick electron transparent SiO₂ windows situated on a silicon substrate.

Typically several silicon substrates are processed, and process yield is sufficient so that about 80 TEM grids can be obtained from 5 silicon substrates having 16 grids per chip. The oxide film is robust, probably due to oxide growth at 1100° C., so that viscous flow of the oxide relieves the compressive stress introduced into the oxide during growth. Therefore, the windows do not tend to buckle or break when the supporting silicon is etched away, and the windows do not appear to be bowed, as there is no evidence of a change in focal plane over the window area. Using the silicon etching conditions described above, grids have most or all oxide windows intact. More aggressive silicon etch conditions, such as maintaining a 90° C. TMAH solution throughout the process, etch faster (˜2-3 hrs) but can result in a lower yield of intact windows (1-4) per grid due to turbulence from the rapid production of gas bubbles as the silicon is etched. The grids are durable and easy to handle with tweezers. The windows are robust to harsh processing conditions such as oxygen plasma or swirling in silicon cleaning solutions such as RCA or piranha solutions.

The method of FIG. 1 is further illustrated in FIG. 2. Thermal oxide layers 202, 203 are formed on a silicon substrate 200, and photoresist layers 204, 205 are coated onto the thermal oxide layers 202, 203, respectively. After photolithographic patterning, openings such as the representative opening 208 are formed in the photoresist layer 204. The substrate and patterned photoresist are exposed to an etch suitable for removing thermal oxide, and openings such as the representative opening 210 are formed in the thermal oxide layer 202 so that a patterned thermal oxide layer is formed. The patterned thermal oxide is then used to define exposed portions of the silicon substrate that can be etched with an etch process that does not etch thermal oxide (or slowly etches thermal oxide) so that thermal oxide windows (such as the representative window 212) are formed in the thermal oxide layer 203. In this process, an SiO₂ layer is patterned to form a mask for etching the silicon substrate, while a photoresist is used to pattern the SiO₂ layer to form the mask. The SiO₂ layers serve as an “etch stop” in the silicon etch. Additional process details of a particular process example are set forth further below.

SEM images of representative grids are shown in FIGS. 3a-3d. FIG. 3a shows the generally octagonal shape of a substrate in which 16 SiO₂ windows are defined. Although the SiO₂ windows are not clearly visible in FIG. 3a, the image of FIG. 3b shows a piece of dust 302 on the SiO₂ window to verify the presence of an SiO₂ window 304. The octagonal shape is due to anisotropy of the TMAH etch. Images of the back side of the substrate (FIGS. 3c-3d) show the Si(111) etch planes in the window and some residual oxide flakes around the edges.

In one example; these grids are used to assemble aligned, close-packed nanoparticles (d_{core}˜1.5 nm) on the grids using a three-step assembly process that includes: (i) surface silanization, (ii) DNA molecular combing, and (iii) nanoparticle assembly. These grids permit TEM to be used for investigation of nanoparticle size, spacing, and coverage on the same substrate used for the assembly reaction. TEM investigation of the assemble nanoparticles shows that nanoparticle purity has a significant effect on the resulting structures. Conventional grids or other analytical methods such as AFM or SEM would not permit such analysis or provide data for such a conclusion.

In a representative application of the silicon grids with electron-transparent SiO₂ windows described above, the SiO₂ window surfaces were chemically modified and DNA was aligned on the chemically modified surfaces to direct the assembly of linear arrays of nanoparticles. With nanoparticle arrays on the electron-transparent windows, TEM could be used to quantify the effects of assembly conditions on nanoparticle size, spacing, and dispersity in the arrays.

In solution, DNA can be used as a template to organize close packed arrays of gold nanoparticles and the spacing between nanoparticles can be controlled by the choice of organic ligand shell on the nanoparticles. See M. G. Warner and J. E. Hutchison, Nat. Mater. 2003, 2, 272-277. In order to make devices from these arrays, the assembly process can be executed directly on surfaces. First, the DNA template is positioned on a chemically-modified surface, and second, close-packed arrays of nanoparticles are assembled on these surface bound DNA scaffolds. While a two-step process of aligning DNA followed by coating with positively charged nanoparticles has been reported (see N. Hidenobu et al., Nano Lett. 2003, 3, 1391-1394), the arrays produced in this way were characterized by AFM, and individual nanoparticles were not resolved. Therefore, the nanoparticle size distribution, interparticle spacing, and overall coverage could not be determined. SiO₂/Si grids as described above are excellent substrates for the investigation of this surface-based assembly chemistry by TEM, and permit measurement of nanoparticle size distribution, interparticle spacing, and overall coverage.

Silanization of the grids and DNA alignment were performed as described by A. Bensimon et al, Science 1994, 265, 2096-2098. The grids were cleaned by a 15 min UV/ozone treatment followed by rinsing with ethanol and ultrapure water, dried at 60° C. for 1 hr, then put in a desiccator with a beaker containing 300 μL n-octyltrichlorosilane for 18 hrs. This vapor phase silanization was performed at room temperature and pressure. The silanized grids were rinsed with ultrapure water to hydrolyze any remaining Si—Cl bonds. The grids were incubated in a solution of λ-DNA (5 μg/mL) in MES buffer (pH=5.5) for 5 min at room temperature, then pulled from solution at 300 μm/s as described in X. Michalet et al., Science 1997, 277, 1518-1523. The DNA arrays were rinsed thoroughly with ultrapure water, then soaked in a solution of Au-thiocholine nanoparticles (1 mg/mL) for 20 min. In order to observe DNA on only one side of the TEM grid, the nanoparticle soak was performed by placing a 10 μL drop of nanoparticle solution on the top side of the grid. The hydrophobic silanized surface prevents the drop from spreading beyond the edge of the grid. Upon completion of the assembly process, the grids were rinsed thoroughly with ultrapure water to remove any nonspecifically bound nanoparticles.

Nanoparticles were synthesized as described previously. Briefly, HAuCl₄ in H₂O reacts with triphenylphosphine (TPP) in toluene in the presence of the phase transfer catalyst tetraoctylammonium bromide. Reduction with NaBH₄ yields ˜1.5 nm TPP stabilized nanoparticles. (2-mercaptoethyl)trimethylammonium iodide (thiocholine) was synthesized. A biphasic ligand exchange between thiocholine in H₂O and the TPP-stabilized nanoparticles in CH₂Cl₂ yielded positively charged, water-soluble Au-thiocholine nanoparticles. See M. G. Warner et al., Chem. Mater. 2000, 12, 3316. The thiocholine stabilized nanoparticles were purified by two rounds of ultracentrifugation at 55,000 rpm. A subset of these Au-thiocholine nanoparticles was further purified by diafiltration (10 volumes, 10 kD) to achieve ‘ultrapure’ Au-thiocholine nanoparticles.

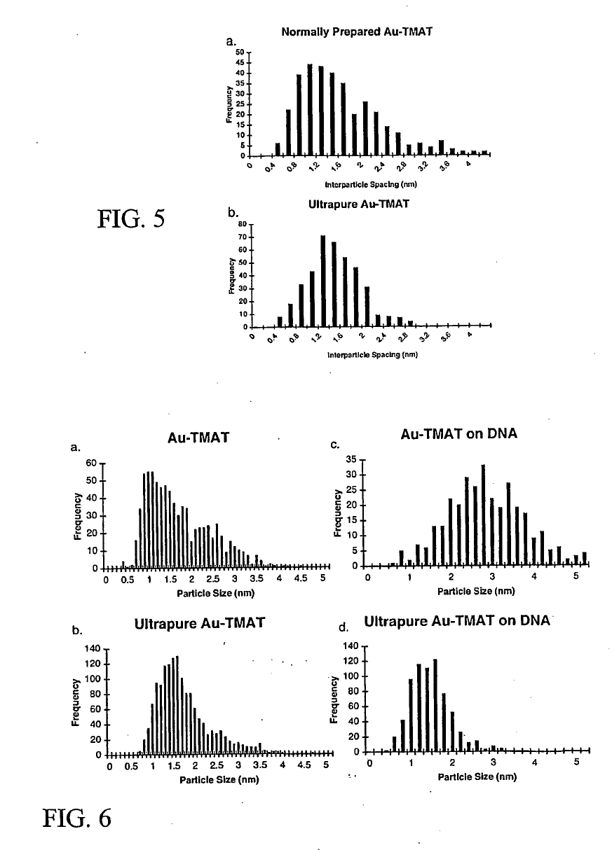

Chemical functionalization of the SiO₂ surface with n-octyltrichlorosilane is a significant consideration for this assembly process as the silanized surface promotes molecular combing of DNA and limits nonspecific adsorption of the positively charged nanoparticles. Low-resolution images (FIG. 4a) show that the nanoparticles form linear, parallel arrays over the entire surface of the substrate. Higher resolution images (FIG. 4b) show that the nanoparticles are close-packed over the entire DNA molecule with an average interparticle spacing of 1.5±0.8 nm (n=353) for the Au-thiocholine particles (FIG. 5a) and 1.4±0.5 nm (n=398) for the ultrapure Au-thiocholine particles (FIG. 5b). An average spacing of 1.4 nm is expected assuming that the particles are close-packed and that the Au-core spacing is dependent on the thickness of the thiocholine ligand shell.

Prior to deposition on DNA, the nanoparticle size distributions were 1.7±0.7 nm (n=792) for the Au-thiocholine particles (FIG. 6a) and 1.7±0.6 nm (n=1476) for the ultrapure Au-thiocholine particles (FIG. 6b). Both appear to have a bimodal distribution that is more pronounced for the normally prepared particles.

Interestingly, after deposition on DNA, the Au-thiocholine particles grew to 2.7±0.9 nm (n=321) (FIG. 6c) while the ultrapure Au-thiocholine particles apparently decreased in size to 1.4±0.5 nm (n=706) (FIG. 6d). Particle size distributions and interparticle spacings were analyzed using NIH ImageJ for Macintosh computers. Particle size was measured as the average of the major and minor axes. The decrease in average diameter and increase in monodispersity of the ultrapure particles on DNA may be a result of size selection toward smaller particles that presumably have a higher charge density than larger particles due to their higher surface to volume ratio.

The difference in the assemblies formed from the normally prepared nanoparticles and ultrapure nanoparticles is surprising. The notable difference between the samples is that the normally prepared Au-thiocholine samples contain traces of free thiocholine ligand associated with the nanoparticles that can be seen as small differences in the NMR spectra. High concentrations of free ligand have been known to destabilize nanoparticles during ligand exchange reactions. See G. H. Woehrle et al., Langmuir 2005, 127, 2172-2183. The increased size of the Au-thiocholine particles may be due to concentration of free ligand near the DNA, resulting in nanoparticle growth on the DNA backbone.

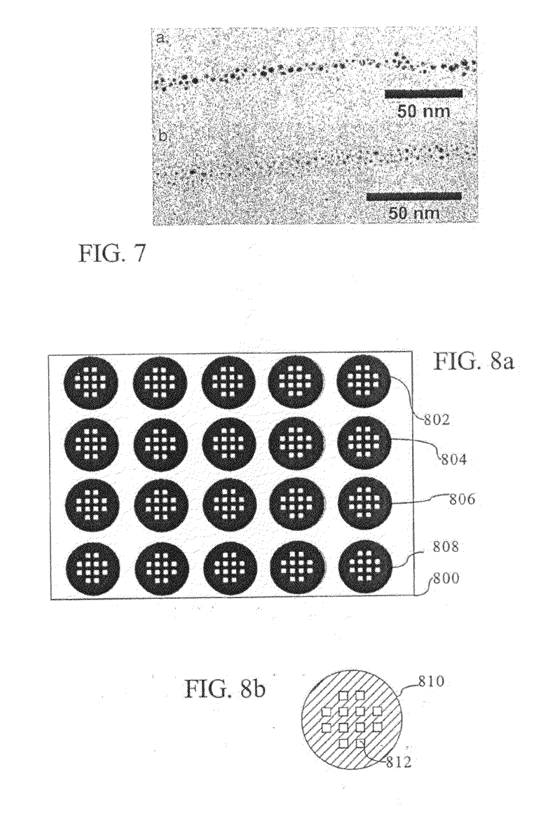

The structures of the normally prepared Au-thiocholine assemblies and the ultrapure Au-thiocholine assemblies are also qualitatively different. The Au-thiocholine particles form linear arrays 1-2 nanoparticles wide (FIG. 7a) while the ultrapure particles form “ribbons” 4-5 nanoparticles wide (FIG. 7b). Some examples of ribbons from solution phase assemblies appear to result from the multivalent character of the positively charged nanoparticles cross-linking several DNA strands, but this should not be the case for the ribbons of FIG. 7b, as the DNA scaffolds are aligned prior to the addition of nanoparticles. Another possibility is that higher order DNA structures such as DNA bundles were aligned on the grid used for the ultrapure particle assemblies. However, all of the DNA assemblies were prepared from the same DNA solution and the same silanization conditions. These differences were reproducible on four grids for each of the two types of nanoparticles, which suggests that the structural differences are not due to differences in the DNA scaffolds. The most plausible explanation is that the normally prepared Au-thiocholine particles also form the ribbon structures, but grow together to form the linear arrays. This could account for both the increase in particle size and decrease in width of the normally prepared particles.

### PROCESS EXAMPLE

For purposes of illustration, a representative process is described in further detail below. A 500 Å thermal oxide was grown at 1100° C. under flowing O₂ on an RCA cleaned chip cut from a 100 μm thick 2″ silicon Ultra Thin™ wafer polished on both sides (Virginia Semiconductor, Fredericksburg, Va.). The chips were coated with a positive photoresist (Shipley S1818) by spin coating at 5000 rpm for 30 s followed by a 1 min soft bake at 100° C. The chips were coated on both sides and the grids were defined by UV photolithography on one side using a contact mask. After developing (Shipley 351 developer) and hard baking the photoresist at 120° C. for 30 min, the exposed SiO₂ was etched for 3 min in 20:1 BOE (Buffered Oxide Etch, 20:1, J.T. Baker). (Buffered oxide etch, 20:1 refers to a solution consisting of 20 parts ammonium fluoride (40%) to 1 part HF (49%).) The photoresist was removed by sonication in acetone followed by an ultrapure water rinse. The chips were then dipped briefly (5 seconds) in 20:1 BOE to remove any oxide that may have formed during the photoresist removal, and rinsed with ultrapure water. The exposed silicon was etched with 10% (wt %) TMAH solution initiated at 90° C. Once it was clear that the etch was underway, the solution was cooled to room temperature and allowed to etch through the silicon overnight. The chips were placed in the solution “patterned side up” to prevent trapping gas bubbles in the etching area. The etch was considered complete when the grids separated from each other. This resulted in TEM grid shaped silicon discs with 500 Å thick electron transparent windows of SiO₂ on one side.

Nanoparticles were synthesized as follows. Briefly, HAuCl₄ in H₂O reacts with triphenylphosphine (TPP) in toluene in the presence of the phase transfer catalyst tetraoctylammonium bromide. Reduction with NaBH₄ yields TPP stabilized nanoparticles. (Hutchison, J. E.; Foster, E. W.; Warner, M. G.; Reed, S. M.; Weare, W. W.; Buhro, W.; Yu, H. Inorganic Syntheses 2004, 34, 228-232.) Thiocholine was synthesized as described previously. (Warner, M. G.; Hutchison, J. E. Nature Mater. 2003, 2, 272) A biphasic ligand exchange between thiocholine in H₂O and the TPP stabilized nanoparticles in CH₂Cl₂ yielded positively charged, water-soluble nanoparticles. (Warner, M. G.; Reed, S. M.; Hutchison, J. E. Chem. Mater. 2000, 12, 3316)

The grids were cleaned by a 15 min. UV/ozone treatment followed by rinsing with ethanol and ultrapure water. The grids were dried at 60° C. for 1 hr, then put in a dessicator with a beaker containing 300 μL n-octyltrichlorosilane overnight. This vapor phase silanization was performed at room temperature and pressure. The silanized grids were rinsed with ultrapure water to react any remaining Si—Cl bonds. The grids were incubated in a solution of λ-DNA (5 μg/mL) in MES buffer (pH=5.5) for 5 min. at room temperature, then pulled from solution 300 μm/s. The grids were then soaked in a solution of thiocholine stabilized 1.4 nm Au-nanoparticles (2.4 mg/mL) for 20 min. In order to observe DNA on only one side of the TEM grid, the nanoparticle soak was performed on only one side of the grid by placing a 10 μL drop of nanoparticle solution on the top side of the grid. The hydrophobic silanized surface prevents the drop from spreading beyond the edge of the grid.

The above representative process example can be modified in arrangement and detail, and is provided to further illustrate aspects of the disclosed technology.

SiO₂ TEM grids can be used for imaging chemically functionalized SiO₂ surfaces ranging from nanoelectronics and photonics to MEMS, and the application described above is a convenient, representative application. Because such grids are fabricated from thermal oxides, they can be used to understand chemistry and assembly on SiO₂ without time consuming and destructive sample prep methods. There is little ambiguity as to how closely the substrate approximates SiO₂, there is no need for time-consuming sample preparation, and the images are high resolution. Such substrates can be used to investigate surface chemistry, nanoparticle chemistry, and alignment methods, and other factors associated with DNA/nanoparticle arrays and structures on thermal oxides, including two dimensional arrays of nanoparticles chemically bound to the SiO₂ surfaces.

The SiO₂ surfaces of these grids can be functionalized in other ways. In some examples, functionalization is directed to fabrication of micro- or nanoscale electrodes on the grids to, for example, take advantage of TEM imaging and analysis of the electrodes and structures within the electrode gaps. Silanization of these grids permits a wide range of surface modifications using organic species. The SiO₂ surface can be functionalized with inorganic species by, for example, atomic layer deposition or other suitable deposition techniques such as evaporation, sputtering, or chemical vapor deposition. For example, Au, Hf, or other metal layer, metal layers, or partial metal layer can be situated on a grid surface. Other functionalizations can be used such as, for example, hafnium-phosphonate functionalizations, and can be based on metals, metal oxides, or organic compounds.

In typical examples, SiO₂ window thickness is selected for electron transparency, and thicknesses less that about 200 nm provide superior transmission. The supporting silicon substrate is typically between about 50 μm and 1 mm thick, but other thickness can be used. SiO₂ window sizes can be varied as well. Silicon is a convenient substrate due to the availability of silicon selective etches for which the SiO₂ window layer serves as an etch stop layer. In typical convenient processes, a silicon layer is etched to form apertures that are terminated at an end with an SiO₂ window.

Window thickness can be critical to obtaining the highest resolution images. To further improve available resolution, thinner windows can be produced. In some cases, windows can be thinned after wet chemical processing is done. For example, the windows can be further thinned by dry etching, even to the point of making the windows “holey,” like holey carbon films. If the thinning is done from the interior, exterior surface chemistry of the silicon dioxide layer or a derivatized version of it can remain unaltered.

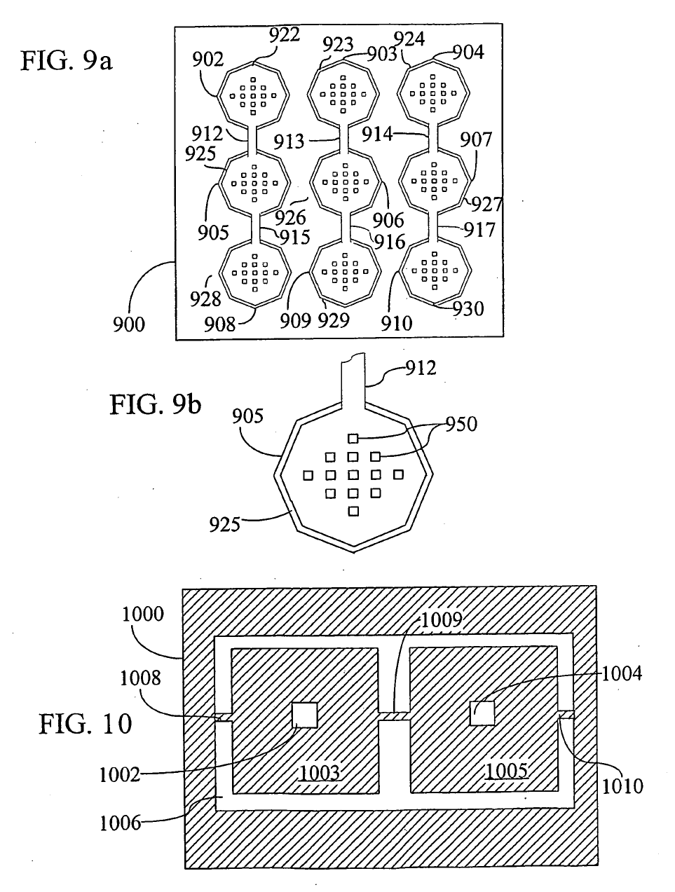

TEM grids such as those described above can be fabricated in sets as shown in FIGS. 9a-9b. Referring to FIG. 9a, a substrate 900 is used to define TEM grids 902-910 that are secured to the substrate 900 with tabs 912-917. The TEM grid 905 is shown enlarged in FIG. 9b. The substrate 900 is typically a silicon substrate, and the TEM grids 902-910 are separated from the substrate 900 with respective channels 922-930. For silicon substrates, the channels 922-930 can be defined by etching the substrate. For example, the channels can be defined by etching a silicon substrate down to an oxide layer in a manner similar to that used to define the TEM grids as described above so that perimeters of the TEM grids 902-910 are attached to the substrate 900 by an oxide layer and/or one or more tabs. Alternatively, the channels can be completely etched through the silicon substrate and the oxide layer, ZZ leaving the TEM grids 902-910 attached to the substrate 900 only at the tabs. The tabs can be unetched or partially etched portions of the substrate 900. For example, the tabs can be associated with portions of the substrate that are etched down to an oxide layer, or partially etched toward an oxide layer. As shown in FIGS. 9a-9b, each TEM grid is shown with two oppositely situated tabs, but one or more tabs can be used, and tabs can be arbitrarily situated at the perimeters of the TEM grids.

The processed substrate of FIG. 9a provides a convenient support for additional substrate processing. For example, conductors can be defined on one or more of the TEM grid windows using conventional photolithographic or other techniques. During the necessary processing steps (such photoresist coating, photoresist patterning, resist development, metal deposition, resist lift off etc.), the TEM grids remain attached to the substrate, and are removed from the substrate upon process completion. The substrate 900 can be large enough for convenient handling (typical dimensions of between about 20 mm and about 250 mm or larger) in contrast to the few mm dimensions of the TEM grids. For electrical investigations of samples situated on an oxide window, electrically conductive materials can be deposited on either window surface. In typical examples, gold conductor lines are defined on the window exterior and not within the recess defined by etching a substrate down to the oxide layer. Conductor lines can be defined using photolithographic or other processes, and the relatively large size of the substrate facilitates such processing.

While TEM grids that include a plurality of TEM transmissive windows can be provided as shown in FIGS. 9a-9b, a single window can be provided such that the single window remains attached to a larger substrate by one or more tabs. An array of single windows can be provided with tabs so that the single windows are individually separable, but are part of a large substrate for convenient processing such as, for example, formation of one or more conductors on one or more windows. For example, referring to FIG. 10, a substrate 1000 includes a first window 1002 and a second window 1004 that are defined as apertures in the substrate 1000 or thinned portions of the substrate 1000. Such thinned portions can terminate in thinned layers of substrate oxides or nitrides having typical thicknesses of between about 10 nm and 500 nm. For example, the windows can be defined as apertures terminating in silicon oxide or nitride layers. In other examples, different substrate materials and window termination materials can be used.

The windows 1002, 1004 are defined in frames 1003, 1005 that are attached to the substrate 1000 with tabs 1008, 1010 and that are separated from the substrate by a channel 1006. The channel can extend completely or partially through the substrate 1000, or can terminate in the same way as the windows 1002, 1004 with, for example, silicon oxide or silicon nitride.

In view of the many possible embodiments to which the principles of the disclosed technology may be applied, it should be recognized that the illustrated embodiments are only representative examples of the disclosed technology.

1. A substrate, comprising a silicon layer in which an aperture is defined, wherein the aperture is terminated at a window surface by an electron-transmissive oxide layer.

2. The substrate of claim 1, wherein the oxide layer is less than about 100 nm thick.

3. The substrate of claim 1, wherein the oxide layer is less than about 50 nm thick.

4. The substrate of claim 1, wherein the silicon layer has a thickness of between about 50 μm and 1 mm.

5. The substrate of claim 1, wherein an exterior surface of the oxide layer is functionalized.

6. The substrate of claim 1, wherein the exterior surface is functionalized by silanization.

7. The substrate of claim 1, further comprising an inorganic layer of thickness less than about 50 nm situated on an exterior surface of the oxide layer.

8. The substrate of claim 6, further comprising an array of nanoparticles situated on the exterior surface of the oxide layer at at least one window.

9. The substrate of claim 1, further comprising a plurality of apertures.

10. A method, comprising:
providing a substrate;
forming a window layer on at least one surface of the substrate;
exposing the substrate to an etchant to form at least one aperture, wherein an etch rate of the substrate as exposed to the etchant is substantially larger than an etch rate of the window layer as exposed to the etchant.

11. The method of claim 10, wherein a surface of the substrate opposite the window layer is patterned to define a location for the at least one aperture.

12. The method of claim 10, wherein window layers are formed on opposing surfaces of the substrate, and one of the window layers is patterned to pattern the substrate.

13. The method of claim 10, wherein the substrate is silicon, and further comprising:
forming window layers of SiO₂ on opposite faces of the substrate;
photolithographically patterning a selected window layer; and
etching the substrate layer based on the photolithographic patterning of the selected window layer so as to define at least one aperture that extends to the other window layer.

14. The method of claim 10, wherein the substrate is about 100 μm thick and the window layers are about 50 nm thick and are formed as thermal oxide of the substrate layer.

15. A substrate, comprising:
a first window frame region in the substrate by a substrate channel;
at least one window defined in the first window frame; and
at least one tab that attaches the first window frame region to the substrate.

16. The substrate of claim 15, wherein the substrate is a silicon substrate, the at least one window consists essentially of silicon oxide, and the substrate channel extends through the substrate.

17. The substrate of claim 16, wherein the window includes at least one electrical conductor situated on a surface of the at least one window.

18. The substrate of claim 15, further comprising:
a plurality of window frames, each window frame defining a plurality of windows; and
a plurality of tabs configured so that each window frame is connected by at least one tab to either a different window frame or the substrate.

19. The substrate of claim 15, wherein the window includes a silicon oxide layer having a thickness of between about 10 nm and 500 nm.

20. A method of making a specimen substrate, comprising:
defining a window frame in a substrate by thinning the substrate in a channel region;
defining an aperture in the window frame, the aperture terminating at a window layer; and
separating the window frame from the substrate at the channel region.

21. The method of claim 20, wherein the window frame is secured to the substrate at at least one tab, and the window frame is separated from the substrate by breaking the tab.

22. The method of claim 21, wherein the substrate is silicon, and the aperture is terminated at a silicon oxide layer having a thickness of between about 10 nm and about 200 nm.

23. The method of claim 22, wherein a plurality of window frames are defined on the substrate.
